(19) United States
(12) Patent Application Publication
(10) Pub. No.: US 2026/0112401 A1
(43) Pub. Date: Apr. 23, 2026

(54) SYSTEMS AND METHODS FOR MEMORY ARRAY ARCHITECTURE WITH COLUMN REPEATER

(71) Applicant: Micron Technology, Inc., Boise, ID (US)

(72) Inventors: Sujeet Ayyapureddi, Boise, ID (US); Gary Howe, Allen, TX (US)

(73) Assignee: Micron Technology, Inc., Boise, ID (US)

(21) Appl. No.: 19/337,290

(22) Filed: Sep. 23, 2025

Related U.S. Application Data
(60) Provisional application No. 63/709,332, filed on Oct. 18, 2024.

(51) Int. Cl. G11C 11/406; G11C 11/408

(52) U.S. Cl. CPC G11C 11/40622; G11C 11/40615; G11C 11/4087

(57) ABSTRACT

Systems, apparatuses, and methods for a memory architecture using a column repeater are disclosed. A memory array includes a first portion and a second portion. A column decoder is coupled to the memory array, and a column repeater is coupled to the second portion of the memory array. The column decoder provides a column selection signal to the column repeater when a received address is associated with the second portion of the memory array, and the column repeater provides the column selection signal to one or more columns in the second portion of the memory array. In some implementations, the column repeater is disposed between the first portion and the second portion.

### CROSS-REFERENCE TO RELATED APPLICATIONS

This application claims the filing benefit of U.S. Provisional Application No. 63/709,332, filed Oct. 18, 2024. This application is incorporated by reference herein in its entirety and for all purposes.

### BACKGROUND

This disclosure relates generally to semiconductor devices, and more specifically to semiconductor memory devices. Disclosed embodiments relate to volatile memory, such as dynamic random-access memory (DRAM). Information is stored on memory cells as a physical signal, such as a charge on a capacitive element. The memory cells may be organized at the intersection of word lines (rows) and bit lines (columns). Information in the memory cells may decay over time. In order to preserve the integrity of the stored information, the memory device may perform refresh operations to restore the information and prevent information from being lost.

### BRIEF DESCRIPTION OF THE DRAWINGS

FIG. 1 is a block diagram illustrating a memory device according to embodiments of the disclosure.

FIG. 2 is a block diagram illustrating bank logic circuits according to embodiments of the disclosure.

FIG. 3 is a block diagram illustrating an architecture of a memory array according to embodiments of the disclosure.

FIG. 4 is a block diagram illustrating an architecture of a memory array according to embodiments of the disclosure.

FIG. 5 is an example timing diagram of operations performed using a memory array according to embodiments of the disclosure.

FIG. 6 is a diagram illustrating an architecture of a memory array according to embodiments of the disclosure.

### DETAILED DESCRIPTION

The present disclosure provides descriptions of non-limiting example embodiments and is in no way intended to limit the scope of the disclosure or its applications or uses. In the following detailed description of embodiments of the present technology, reference is made to the accompanying drawings, which form a part hereof and in which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art, so as not to obscure the description of embodiments of the disclosure. The following detailed description is therefore not to be taken as limiting, and the scope of the disclosure is defined only by the appended claims.

A memory device includes a memory array. The memory array includes a number of memory cells at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

Information in a memory array may be accessed by performing access operations, such as read or write operations. During an example access operation, a word line may be activated based on a row address. Selected memory cells along that active word line may have their information read from, or written to, based on which bit lines are selected by a column address. The bit lines are coupled to sense amplifiers. The sense amplifiers sense a voltage on the bit line from the memory cells along the active word line and amplify it into a signal in a read operation or drive a voltage to the memory cell along the active word line in a write operation. Each bank is divided into sections. In some embodiments, a bank is divided into sections, with each section separated from its neighboring sections by a strip of sense amplifiers that are coupled to the bit lines extending into the neighboring sections. Accordingly, the row address may specify which section is being accessed. The sense amplifiers are shared by the neighboring sections, with the sense amplifiers used by one of the neighboring sections during an access operation.

Information in the memory cells decays over time. To prevent information loss, the memory array may be refreshed on a row-by-row basis (e.g., as part of an auto-refresh and/or self-refresh mode), where the memory cells along each row are refreshed periodically to restore the stored information to an initial value. Such refresh operations may be referred to as sequential refresh operations or normal refresh operations, as the memory may use some sequence logic (e.g., a counter) to generate refresh addresses used to determine which word lines are refreshed. Targeted refresh operations may also be performed to refresh word lines associated with aggressor word lines.

In some examples, background refresh operations may be performed, which may refresh targeted word lines or word lines identified using sequence logic. In a background refresh operation, a memory device receives an access operation which allows an opportunity for a refresh operation on memory cells other than the memory cells that are accessed for the access operation. For example, the memory determines if a refresh operation is needed and possible, and then performs a refresh operation on a word line in a different section than the section being accessed. The word lines may be active at overlapping periods of time. In this way, refreshes may occur while the memory is being accessed. By contrast, refresh operations performed on their own, such as in response to a refresh command from a controller, may generally be referred to as standalone refresh operations. The use of background refresh operations may help decrease the number of standalone refresh operations. The use of background refresh operations may decrease a downtime of the memory because both access operations and refresh operations may be performed, unlike standalone refresh operations, which may not allow for access operations.

While technologies implementing background refreshes may provide the foregoing and other benefits, the activation of both an accessed word line and a refreshed word line may cause sense amplifier collisions (e.g., where a same sense amplifier is needed for both an access operation and a background refresh operation) or other problems. To address these problems and provide other benefits, the present disclosure is drawn to apparatuses, systems, and methods for memory array architectures in which an array may be arranged in two halves with each half having its own edge arrays. In various embodiments, a column repeater may be disposed between the two halves of the array, which can enable independent column selection in each half of the array. For example, the disclosed technology may enable independent operation of per-row activation counting (PRAC) in each half. In an example embodiment, a memory array includes a first portion and a second portion, and a column repeater is coupled to the second portion of the memory array. When a received address is associated with the second portion of the memory array, a column decoder is configured to provide a column selection (CS) signal to the column repeater, and the column repeater provides the CS signal to at least one column in the second portion of the memory array. For example, the received address may indicate a row to be refreshed as part of a background refresh operation, and the CS signal may be provided to a column configured for per row activation counting (PRAC). An access operation may be performed in the first portion of the memory array, and the column repeater allows the at least one column in the second portion of the memory array to be activated without interfering with the access operation in the first portion of the memory array.

While example embodiments are described in which an array is divided in half with a column repeater disposed between the two halves, the present disclosure contemplates other embodiments in which the array may be structured in other ways, such as embodiments having multiple column repeaters and/or more than two array portions. Additionally, while example embodiments relate to independent column selection for PRAC, it will be appreciated that other independent operations may be performed using the disclosed technology, such as independent column selection for memory cells storing other kinds of data. In some embodiments, the column repeater may comprise a second column decoder, and in some embodiments the column repeater may be included in a column decoder.

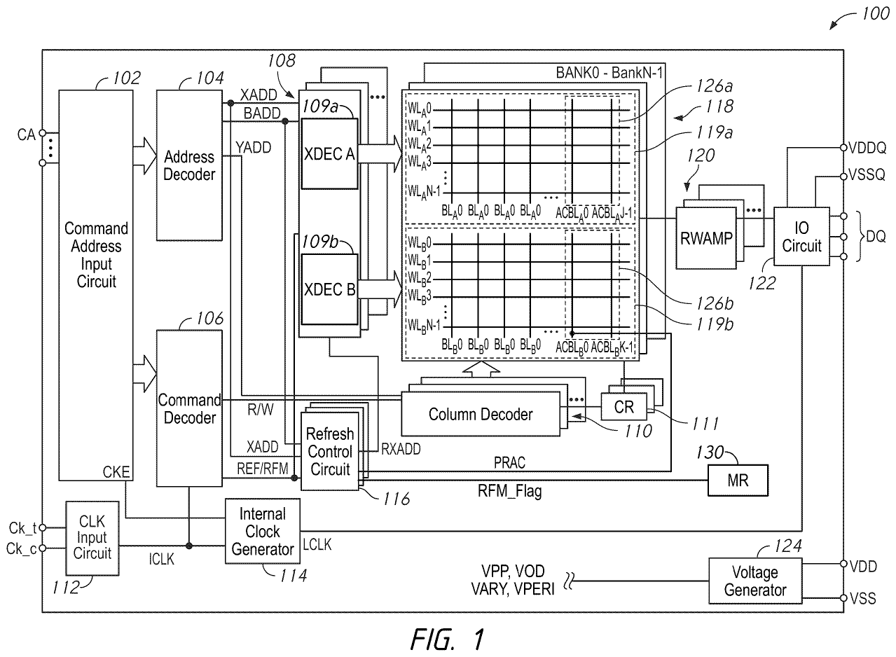

FIG. 1 is a block diagram illustrating a memory device 100 according to embodiments of the disclosure. The memory device 100 may be, for example, a DRAM device integrated on a single semiconductor chip. The memory device 100 may be operated by a host or controller (not shown). The controller may be any device (or collection of devices) which stores information on the memory device 100. For example, the controller may be a processor. In some embodiments, the controller and memory device 100 may be packaged together on a single integrated circuit. In some embodiments, the controller and memory device 100 may be separate. In some embodiments, the controller may operate multiple memory devices 100.

The memory device 100 includes a memory array 118. The memory array 118 may be organized into one or more memory banks. In the embodiment of FIG. 1, the memory array 118 is shown as including N memory banks BANK0-BANKN-1. For example there may be 2, 4, 8, or 16 memory banks. More or fewer banks may be included in the memory array 118 of other embodiments. Each memory bank includes a plurality of word lines WL (rows), a plurality of bit lines BL (columns), and a plurality of memory cells arranged at intersections of the plurality of word lines WL and the plurality of bit lines BL. Each bank is associated with a value of a bank address BADD.

The selection of the word line WL is performed by bank row decoders 108 and the selection of the bit lines BL is performed by a column decoder 110 and/or a column repeater 111. Certain circuits, such as the bank row decoders 108, the column decoder 110, and the column repeater 111 are repeated on a bank-by-bank basis. For example, if there are N banks there may be N bank row decoders 108, N column decoders 110, and N column repeaters 111. Certain other circuits of the memory device 100 may also be repeated on a bank-by-bank basis. For example, each bank may have an associated bank logic region, which includes the circuits associated with that bank.

The bit lines BL are coupled to a respective sense amplifier (SAMP). The sense amplifiers are coupled to local input/output (LIO) and global input/output (GIO) to read/write amplifiers (RWAMP) 120 and through those to the input/output circuits 122 of the memory device 100. During an access operation, the bank row decoder circuits 108 activate a word line specified by the row address. The activated word line couples the memory cells along that word line to the intersecting bit lines. During a read operation, the sense amplifiers amplify the signal along that bit line to a voltage that represents the logical level stored in the memory cell. During a write operation, the sense amplifiers receive a signal indicating a logical level to be written and amplify it onto the bit line and through the bit line to the memory cell. After operations, the bank row decoder circuits 108 pre-charge the word line.

The banks may be divided into one or more portions 119, each of which is associated with a respective row decoder 109. For example, FIG. 1 shows two portions 119a and 119b, each with their own respective set of word lines WL_{A} and WL_{B} and their own respective set of bit lines BL_{A} and BL_{B}. The different portions may have a same or different number of word lines, bit lines, or combinations thereof. The bank row decoder circuits 108 for that bank include two row decoders 109a and 109b. The row decoder 109a is associated with the portion 119a and the row decoder 109b is associated with the portion 119b. The portions 119 may be address spaces, and the portions may be identified based on row addresses. One or more bits of the row address XADD may specify which portion to perform the access operation in. More portions per bank may be used in other example embodiments.

The memory device 100 may employ a plurality of external terminals coupled to the controller. The external terminals include command and address (CA) terminals coupled to the controller along a command and address bus to receive commands and addresses. Other external terminals include clock terminals to receive clock signals CK_t and CK_c along a clock bus, data terminals DQ to send and receive data along a data bus, and power supply terminals to receive power supply potentials such as VDD, VSS, VDDQ, and VSSQ.

The clock terminals are supplied by the controller with external clocks CK_t and CK_c that are provided to an input circuit 112. The external clocks may be complementary. The input circuit 112 generates an internal clock ICLK based on the CK_t and CK_c. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The CA terminals may be supplied with memory addresses by the controller. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include access commands such as an activate command ACT, one or more column commands such as read or write, and pre-charge command PRE, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations.

As part of an example write operation, the CA terminals receive an activate command ACT and a row address. The row address includes one or more bits which specify which portion 119 to activate. The selected row decoder 109 activates the specified word line. The non-selected row decoder 109 may activate an associated word line in the non-selected portion and perform a background refresh operation in one or more rows in the non-selected portion (e.g., based on a background refresh command provided by the refresh control circuit 116), such as to refresh a row identified by the refresh control circuit 116. The CA terminals receive a column command, in this case write, along with a column address. The column decoder couples bit lines specified by the column address YADD to the LIO and GIO lines. The input/output circuit 122 receives data along the data terminals DQ. The data is provided through the RWAMP 120 through the LIO and GIO lines to the specified bit lines. When the controller is done performing operations on the word line, the memory device 100 receives a pre-charge command PRE, and the active word lines are pre-charged.

As part of an example read operation, the CA terminals receive an activate command ACT and a row address. The row address includes one or more bits which specify which portion 119 to activate. The selected row decoder 109 activates the specified word line. The non-selected row decoder 109 may activate an associated word line in the non-selected portion and perform a background refresh operation in one or more rows in the non-selected portion (e.g., based on a background refresh command provided by the refresh control circuit 116), such as to refresh a row identified by the refresh control circuit 116. The CA terminals receive a column command, in this case read, along with a column address. The column decoder couples bit lines specified by the column address YADD to the LIO and GIO lines. The sense amplifiers amplify the signal from the intersecting memory cells along the bit lines to the LIO and GIO lines through the RWAMP 120 to the IO circuit 122. The IO circuit 122 provides the read data to the data terminals DQ. When the controller is done performing operations on the word line, the memory device 100 receives a pre-charge command PRE, and the active word lines are pre-charged.

The memory device 100 may also receive commands causing it to carry out standalone refresh operations. For example, the controller may issue a refresh command REF or a refresh management command RFM. Responsive to either the REF command or the RFM command, the refresh control circuit 116 may perform one or more refresh operations. As part of a refresh operation, the refresh control circuit 116 issues a refresh address RXADD, and the bank row decoder circuits 108 may refresh one or more word lines based on the refresh address RXADD. The number and type of refresh operations performed may vary based on whether REF or RFM is received. In some embodiments, the refresh control circuit 116 may be repeated on a bank-by-bank basis, similar to the row decoder 108, the column decoder 110, and the column repeater 111.

The refresh commands REF and RFM are supplied to the refresh control circuit 116. The refresh control circuit 116 supplies one or more refresh addresses RXADD to the row decoder 108, which refreshes one or more word lines WL identified by the refresh row address RXADD. For example, in some embodiments, the refresh control circuit 116 may perform a mix of normal (or sequential) refresh operations and targeted refresh operations responsive to the refresh command REF, and may perform targeted refresh operations responsive to the RFM command RFM. In some embodiments, the refresh control circuit 116 may perform normal refresh operations responsive to REF and targeted refresh commands responsive to RFM. The memory device 100 includes a mode register 130, which may store and/or provide various settings information, such as a refresh management flag RFM_Flag.

The memory device 100 uses per row activation counting (PRAC) to identify aggressor rows, and the refresh control circuit 116 may cause targeted refresh operations to be performed on victim rows (e.g., one or more rows adjacent to an aggressor row). In the example embodiment of FIG. 1, some of the memory cells of the array 118 may be set aside to store access counts. The memory cells 126 which are set aside for such a purpose may generally be referred to as counter memory cells 126. The counter memory cells 126 may store access count values PRAC, each of which is associated with one of the word lines. The count value PRAC may be stored as a binary number. In some embodiments, each bit is stored in a memory cell along the word line. The counter memory cells are stored in memory cells along access count bit lines ACBL. The number of counter memory cells along each word line may be based on a number of bits of the count value PRAC.

In some embodiments, the counter memory cells 126 and access count bit lines may be referred to as such due to their use (storing the count values) and in some embodiments may be structurally similar to, or identical to, the other memory cells and bit lines of the array. The count values PRAC may be used to determine if the associated word line is an aggressor or not. For example, each time the word line is activated, a count value PRAC associated with that row is updated (e.g., incremented). If the updated count crosses a threshold, then the row address XADD may be stored as an aggressor and the count value may be updated by being reset to an initial value (e.g., 0).

In various embodiments, the column decoder 110 is coupled to the memory array 118, while the column repeater 111 is coupled to one of the portions 119 of the memory array 118, which allows for independent column selection in each portion 119. For example, the column repeater 111 may be coupled to bit lines in the portion 119a. When a received address is associated with the portion 119a, the column decoder 110 may provide a column selection signal for the received address to the column repeater 111, and the column repeater 111 may provide the column selection signal to a column in the portion 119a. By contrast, a received address associated with the portion 119b would not be repeated, and the column decoder 110 would provide a respective column selection signal to a column in the portion 119b. In this way, column selection can be performed independently in each portion 119 of the memory array 118. The column decoder 110 may determine whether a received address (e.g., for an access operation or a refresh operation) is associated with the portion 119a or the portion 119b based on one or more bits of a row address.

In various embodiments, the column repeater 111 may be disposed between the portion 119a and the portion 119b. In various embodiments, the column repeater 111 may be included in the column decoder 110. In various embodiments, the column repeater 111 may be specific to column selection in counter memory cells 126a of the portion 119a, while the column decoder 110 is used to perform column selection in counter memory cells 126b of the portion 119b. In these and other embodiments, the column decoder 110 may be used for column selection for data access in both the portion 119a and the portion 119b, either by providing a column selection signal directly to respective columns or by repeating the column selection signal in the portion 119b through the column repeater 111. Additionally or alternatively, column selection signals for column selection related to the counter memory cells 126b of the portion 119b may not be repeated through the column repeater 111.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

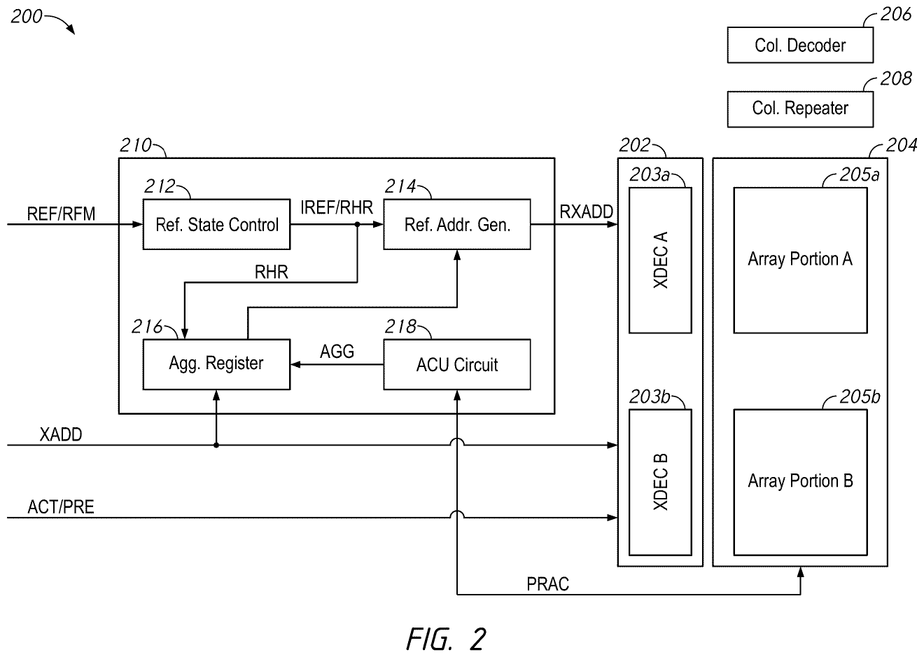

FIG. 2 is a block diagram illustrating bank logic circuits 200 according to embodiments of the disclosure. The bank logic circuits 200 may, in some embodiments, implement a part of a memory device such as 100 of FIG. 1. For example, the bank logic circuits 200 may represent selected circuits in a bank logic region associated with a bank of the memory array 118 of FIG. 1. The bank logic circuits 200 illustrated in FIG. 2 include a refresh control circuit 210 (e.g., 116 of FIG. 1), a row decoder 202 (e.g., 108 of FIG. 1), a memory bank 204 (e.g., included in 118 of FIG. 1), a column decoder 206 (e.g., 110 of FIG. 1), and a column repeater 208 (e.g., 111 of FIG. 1). Certain other circuits that may be part of the bank logic are omitted from the view of FIG. 2 for ease of illustration. In some embodiments, the column repeater 208 may be disposed between portions of the memory bank 204.

The refresh control circuit 210 includes a refresh state control circuit 212, a refresh address generator 214, an aggressor register 216, and an access count update (ACU) logic circuit 218. The refresh state control circuit 212 receives signals such as REF and RFM and determines how many refresh operations should be performed and what types. Additionally, the refresh state control circuit 212 may cause performance of background refresh operations associated with access operations. The refresh address generator circuit 214 generates the refresh address RXADD. The aggressor register 216 stores one or more identified aggressor addresses HitXADD. The ACU logic circuit 218 updates the PRAC count when a word line is accessed and uses the PRAC to determine if the word line is an aggressor. The memory bank 204 is split into a portion 205a (e.g., 119a of FIG. 1) associated with a row decoder 203a (e.g., 109a of FIG. 1) and a portion 205b (e.g., 119b of FIG. 1) associated with a row decoder 203b (e.g., 109b of FIG. 1).

The refresh state control circuit 212 receives signals such as REF and RFM and determines how many refresh operations to perform and of what type(s). The refresh state control circuit 212 may also cause performance of background refresh operations, which may be performed without receiving the signals REF and RFM. The refresh state control circuit 212 provides an internal refresh signal IREF to indicate a normal refresh operation and a targeted refresh signal RHR to indicate a targeted refresh operation. In some example implementations, the refresh state control circuit 212 may perform multiple refresh operations for each time REF or RFM is received and/or as part of a background refresh. For example, two, four, six, more or fewer refresh operations may be performed. In some example implementations, the refresh state control circuit 212 may perform only normal refresh operations responsive to REF and perform targeted refresh operations responsive to RFM. In some example implementations the refresh state control circuit 212 may perform a mix of normal and targeted refresh operations responsive to REF and perform targeted refresh operations responsive to RFM.

The refresh address generator 214 generates a refresh address RXADD responsive to IREF, RHR, or combinations thereof. For example, responsive to IREF, indicating a normal refresh address, the refresh address generator circuit 214 generates the refresh address RXADD based on sequence logic. For example, the refresh address generator circuit 214 may include a counter, which increments a value to generate a refresh address for normal refresh operations. Responsive to a targeted refresh operation (e.g., the signal RHR) the refresh address generator 214 uses an aggressor address HitXADD to generate one or more refresh addresses. For example, the refresh addresses may represent the word lines which are adjacent to the word line associated with HitXADD. In some embodiments, during a normal refresh operation multiple word lines may be refreshed, while during a targeted refresh operation a single word line may be refreshed. For example, the refresh address generated for a normal refresh operation may be truncated, and every word line which has an address which shares that truncated portion in common may be refreshed by the row decoder 202. Normal refreshes, targeted refreshes, or both may be performed as part of a background refresh operation.

When a word line is accessed, its associated PRAC count is read out to the ACU logic circuit 218. The row address XADD may indicate if it is associated with the bank portion 205a or the bank portion 205b. For example, a portion select bit of the row address may have a first state if the row address specifies the portion 205a or a second state if the row address specifies the portion 205b. In an example implementation, the bank may be organized such that all of the row addresses that have a most significant bit (MSB) at a logical high are in the portion 205a and all of the row addresses which have a MSB at a logical low are in the portion 205b. Accordingly, the most significant bit may act as the portion select bit.

Responsive to an activate command ACT, the row decoder 203 selected by the portion select bit of the row address activates a word line in the respective portion 205 for the access operation. The row decoder 203 not selected by the portion select bit also activates a word line to perform a background refresh operation in one or more rows of the unselected portion of the memory bank 204. In embodiments of the disclosure, the column repeater 208 is used to perform column selection in the portion 205a of the memory bank 204. For example, the column decoder 206 may provide a column selection signal to the column repeater 208 to reset a PRAC count value when a refresh address is associated with the portion 205a, and the column repeater 208 provides the column selection signal to a respective column. When a refresh address is associated with the portion 205b, the column selection signal is not provided to the column repeater 208, and the column decoder 206 provides the column selection signal directly to a respective column to reset the PRAC count value. In various embodiments, the column repeater 208 is specific to column selection of PRAC bits (e.g., 126a of FIG. 1) used to maintain a PRAC value for a respective row. The column decoder 206 may determine whether to provide an activate signal to the column repeater 208, for example, based on a portion select bit in a row address.

As part of an ACU operation, the ACU logic circuit 218 receives a PRAC value responsive to an activate command ACT. The ACU logic circuit 218 updates the PRAC value, for example by incrementing the PRAC value. If the PRAC value has not crossed a threshold, the updated PRAC value is written back to its original location in the bank 204. If the PRAC value has crossed a threshold, the ACU logic circuit 218 provides an aggressor signal AGG. In some embodiments, responsive to the PRAC value crossing the threshold, the ACU logic circuit 218 resets the PRAC value, for example to an initial value such as 0.

The aggressor register 216 includes a number of ‘slots’ which may be used to store aggressor addresses. For example, each slot may include a number of latch circuits the length of a row address. Responsive to the aggressor signal AGG, the register 216 adds the current row address XADD to the register. The register 216 may act as a FIFO register in some embodiments.

In embodiments of the disclosure, the column decoder 206 and the column repeater 208 enable independent column selection in the portion 205a and the portion 205b. For example, the column decoder 206 may perform column selection directly in the portion 205b in association with an access operation at a row address XADD and a column address YADD (not shown) (e.g., to access a specified memory cell and to increment an associated PRAC count value), while the column decoder 206 may provide a signal to the column repeater 208, which is repeated to perform column selection associated with a PRAC count value associated with a refresh operation at a refresh address RXADD (e.g., to reset the PRAC count value in association with the performance of the refresh operation). Similarly, the column decoder 206 may perform column selection directly in the portion 205b in association with a refresh operation in one or more rows in the portion 205b, while the column decoder 206 may provide a signal to the column repeater 208, which is repeated to perform column selection associated with an access operation in the portion 205a.

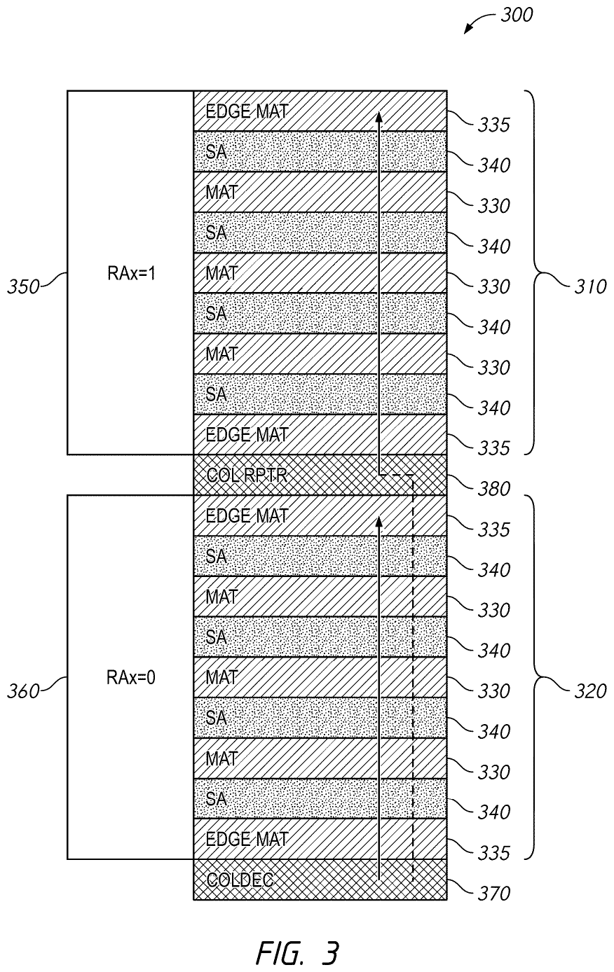

FIG. 3 is a block diagram illustrating an architecture of a memory array 300 according to embodiments of the disclosure. For example, the memory array 300 can be the array 118 of FIG. 1 and/or the array 204 of FIG. 2. The memory array includes a portion 310 and a portion 320 (e.g., 119a & 119b of FIG. 1, respectively). The portion 310 and the portion 320 each include a plurality of memory mats 330, as well as edge mats 335 disposed at respective edges of the portion 310 and the portion 320. The memory mats 330 and edge mats 335 comprise memory cells arranged in rows and columns. Sense amplifier regions 340 comprising a plurality of sense amplifiers are coupled to respective memory mats 330 and/or edge mats 335, and the sense amplifiers are used when accessing memory cells of the memory mats 330 and/or edge mats 335. The edge mats 335 may have fewer rows than the memory mats 330. In various embodiments, the edge mats 335 may use various architectures, such as folded bit line architectures, and the edge mats 335 may be coupled to single-ended sense amplifiers (not shown).

The portion 310 of the memory array 300 is coupled to a row decoder 350 (e.g., 109a of FIG. 1), and the portion 320 of the memory array 300 is coupled to a row decoder 360 (e.g., 109b of FIG. 1). The memory array 300 is also coupled to a column decoder 370, which is used to perform column selection in the portion 310 and the portion 320. A column repeater 380 is coupled to the column decoder 370 and the portion 310 of the memory array 300, and the column repeater 380 is used to perform at least some column selection in the portion 310. As described herein, architectures according to the disclosed technology can be used to perform operations in the portion 310 and the portion 320, and column selection (e.g., associated with a PRAC count value) can be performed independently in the respective portions. In an example embodiment, the column repeater 380 is used to perform column selection at memory cells in the portion 310 used to store PRAC values of respective rows.

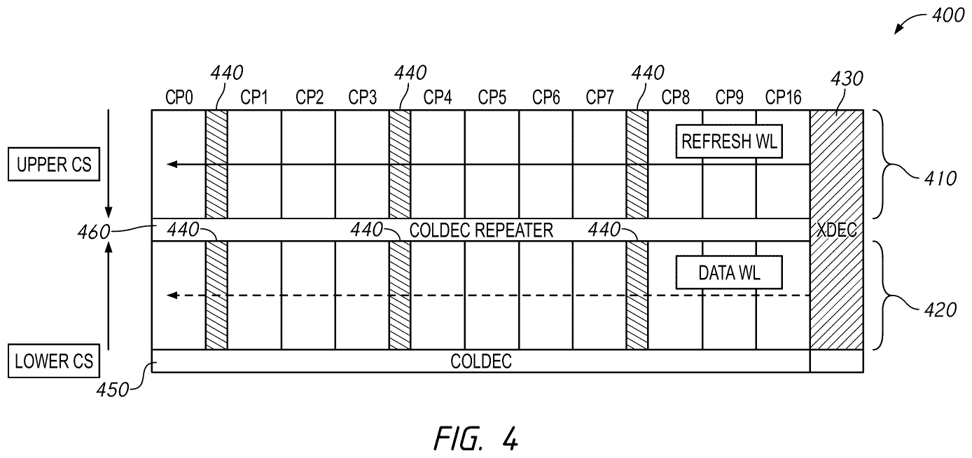

FIG. 4 is a block diagram illustrating an architecture of a memory array 400 according to embodiments of the disclosure. For example, the memory array 400 can be the array 118 of FIG. 1 and/or the array 204 of FIG. 2. The memory array 400 includes a portion 410 and a portion 420 (e.g., 119a & 119b of FIG. 1, respectively). The memory array 400 is coupled to a row decoder 430 (e.g., 108 of FIG. 1), which is used to perform row selection associated with, for example, access operations and refresh operations.

The memory array 400 comprises memory cells arranged in rows and columns. The memory array 400 may include counter columns 440, which comprise counter memory cells to store PRAC count values (e.g., 126 of FIG. 1), and data columns CP0-CP16, which comprise memory cells to store data.

The memory array 400 is also coupled to a column decoder 450, which is used to perform column selection in the portion 410 and the portion 420, and to a column repeater 380, which is used to perform at least some column selection in the portion 410. For example, the column repeater 460 may be used to perform column selection in counter columns 440 of the portion 410 (e.g., to reset a PRAC count value in association with a refresh operation on a row in the portion 410).

In an example implementation, an access operation is performed along a word line DATA WL in the portion 420, while a background refresh operation is performed along a word line REFRESH WL in the portion 410. The column decoder 450 may perform column selection associated with the access operation by providing a column select signal to a column identified using a column address, and a memory cell is accessed at the intersection of the selected column and the word line DATA WL in the portion 420. The column decoder 450 further performs column selection in the portion 420 to select a counter column 440 in the portion 420 (e.g., to increment a PRAC count value) in association with the access operation. Additionally, the column decoder 450 may provide a column select signal to the column repeater 460 to select one or more counter columns 440 in the portion 410 associated with performance of the refresh operation (e.g., to reset a PRAC count value).

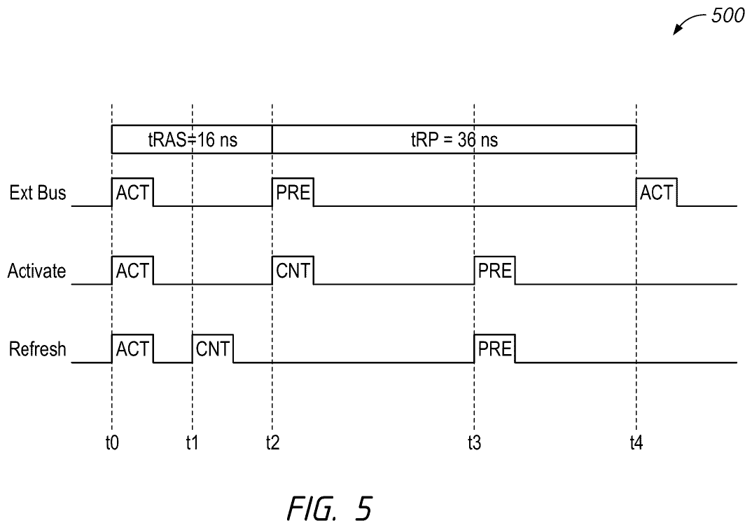

FIG. 5 is an example timing diagram 500 of operations performed using a memory array according to embodiments of the disclosure. For example, the timing diagram 500 may illustrate operations performed using the memory array 400 of FIG. 4. Additionally, the timing diagram 500 may illustrate operations performed using the memory device 100 of FIG. 1.

The timing diagram 500 includes system commands (Ext Bus), which represent commands received at CA terminals of the memory device. The timing diagram 500 also includes internal commands sent to an activated word line (Activate) being accessed, and internal commands sent to a refresh word line (Refresh) being refreshed as part of a background refresh operation associated with the access operation. The refresh word line may be in a first portion of the memory array (e.g., 410 of FIG. 4), and the activated word line may be in a second portion of the memory array (e.g., 410 of FIG. 4).

At a time t₀, and during row activation time (tRAS), the memory device receives an activate command ACT at an external bus, and an internal activate command ACT is provided to the activated word line and the refresh word line. As described herein, the activated word line is identified based on a row address associated with an access command, and the activated word line is activated by a row decoder (e.g., 108 of FIG. 1). A refresh control circuit (e.g., 116 of FIG. 1) of the memory device may determine that a background refresh operation will be performed in association with the access operation, and the refresh control circuit identifies the refresh word line to be refreshed based internal logic of the refresh control circuit (e.g., sequence-based logic or row hammer refresh logic). The refresh word line is activated by the row decoder, or by a different row decoder. The activate command ACT causes activation of both the activated word line and the refresh word line. Responsive to the activate command ACT, an access operation is performed at the activated word line, and a background refresh operation is performed at the refresh word line.

At a time t₁, and during tRAS, a count operation CNT is performed at one or more counter memory cells (e.g., 119 of FIG. 1) associated with the refresh word line. The count operation CNT for the refresh word line may be to reset a PRAC count value associated with the refresh word line. As part of the count operation, column selection may be performed to select one or more columns corresponding to the one or more counter memory cells. To perform column selection, a column select signal is provided by a column decoder (e.g., 450 of FIG. 4) to a column repeater (e.g., 460), and the column repeater provides the column select signal to the one or more columns.

At a time t₂, and during row precharge time (tRP), a precharge command PRE is received at the external bus, and a count operation CNT is performed at one or more counter memory cells (e.g., 119 of FIG. 1) associated with the activated word line. The count operation CNT for the activated word line may be to increment a PRAC count value associated with the activated word line. As part of the count operation, column selection may be performed to select one or more columns corresponding to the one or more counter memory cells. To perform column selection, a column select signal is provided by the column decoder to the one or more columns. Because the activated word line is in the second portion of the memory array (e.g., 420 of FIG. 4), the column select signal is not provided to the column repeater.

At a time t₃, an internal precharge command PRE is provided to the activated word line and the refresh word line, and both word lines are deactivated.

At a time t₄, and after tRP, a second activate command ACT is received at the external bus, and the illustrated operations may be repeated (e.g., to perform an access operation at a different activated word line and an associated background refresh operation at a different refresh word line).

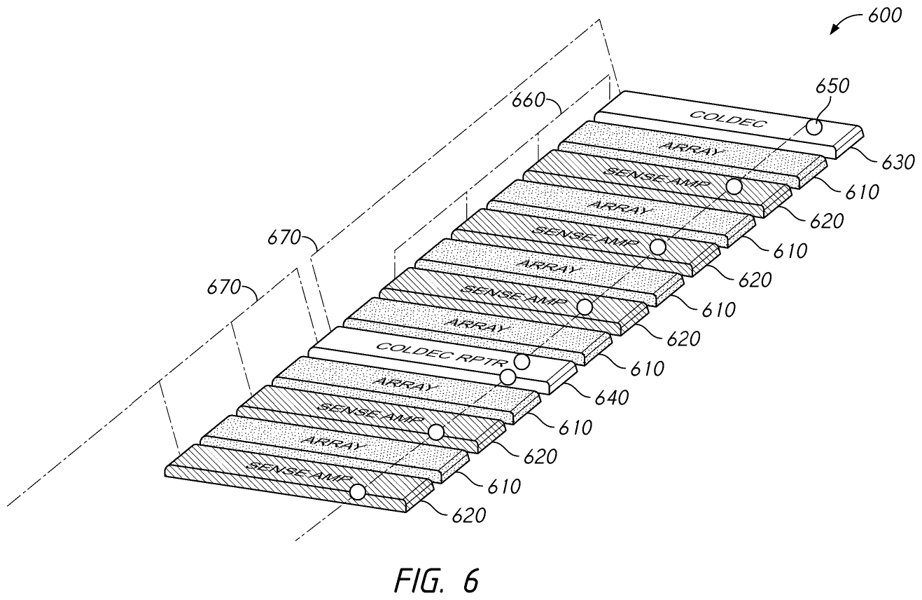

FIG. 6 is a diagram illustrating an architecture of a memory array 600 according to embodiments of the disclosure. The memory array 600 can be, for example, the array 118 of FIG. 1.

The memory array 600 includes a plurality of memory mats 610. The memory mats 610 comprise memory cells arranged in rows and columns. Sense amplifier regions 620 comprising a plurality of sense amplifiers are coupled to respective memory mats 610, and the sense amplifiers are used when accessing memory cells of the memory mats 610.

The memory array 600 is coupled to a column decoder 630 and a column repeater 640. As described herein, the column decoder 630 can be used to perform column selection, such as column selection for access operations and column selection for counter memory cells (e.g., to increment or reset PRAC count values), while the column repeater 640 can be used to perform at least some column selection in only a portion of the memory array 600.

In the illustrated embodiment, a set of conductive lines 650 couples the column decoder 630 to memory mats 610 across the memory array 600, and the set of conductive lines 650 can be used to perform column selection of memory cells storing data across the memory array 600 (e.g., in both an upper and lower portions of the memory array 600). In some embodiments, the set of conductive lines 650 couples the column decoder 630 to all memory mats 610 of the memory array 600 directly. In other embodiments, the set of conductive lines 650 includes conductive lines to couple the column decoder 630 to the column repeater 640. Column select signals for the upper portion of the memory are repeated to perform column selection of the memory cells storing the data in the upper portion of the memory array 600.

A set of conductive lines 660 couples the column decoder 630 to memory mats 610 across the lower portion of the memory array 600, and the set of conductive lines 660 is used to perform column selection of counter memory cells (e.g., 126 of FIG. 1) used to store count values (e.g., PRAC count values) for respective rows in the lower portion of the memory array 600. The column selection can be performed to set a count value, such as to increment a PRAC count value in association with an access operation at a respective row of the memory array 600. The set of conductive lines 660 is not coupled to the column repeater 640 or any memory mats in the lower portion of the memory array 600. As a result, column select signals provided via the set of conductive lines 660 are not repeated across the column repeater 640 to the lower portion of the memory array 600.

A set of conductive lines 670 couples the column decoder 630 to the column repeater 640 and the memory mats 610 in the upper portion of the memory array 600. The set of conductive lines 670 is used to perform column selection of counter memory cells (e.g., 126 of FIG. 1) used to store count values (e.g., PRAC count values) for respective rows in the upper portion of the memory array 600. As described herein, a column select signal is provided from the column decoder 630 to the column repeater 640, and the column repeater provides the column select signal to a respective column. The column selection can be performed to set a count value, such as to reset a PRAC count value in association with a background refresh operation at a respective row of the memory array 600. The architecture of the memory array 600 enables independent column selection in the respective portions (e.g., halves) of the memory array 600 by selectively repeating column select signals across the column repeater 640.

It is to be appreciated that any one of the examples, embodiments or processes described herein may be combined with one or more other examples, embodiments and/or processes or be separated and/or performed amongst separate devices or device portions in accordance with the present systems, devices, and methods.

Finally, the above discussion is intended to be merely illustrative of the present system and should not be construed as limiting the appended claims to any particular embodiment or group of embodiments. Thus, while the present systems, apparatuses, and methods have been described in particular detail with reference to example embodiments, it should also be appreciated that modifications and alternative embodiments may be devised by those having ordinary skill in the art without departing from the broader and intended spirit and scope of the present technology as set forth in the claims that follow. Accordingly, the present disclosure is to be regarded in an illustrative manner and is not intended to limit the scope of the appended claims.

What is claimed is:

1. An apparatus comprising:
a memory array comprising a first portion and a second portion;
a column decoder coupled to the memory array; and
a column repeater coupled to the second portion of the memory array, wherein the column decoder is configured to provide a column selection signal to the column repeater when a received address is associated with the second portion of the memory array, and wherein the column repeater is configured to provide the column selection signal to at least one column in the second portion of the memory array.

2. The apparatus of claim 1, wherein the column repeater is disposed between the first portion of the memory array and the second portion of the memory array.

3. The apparatus of claim 1, wherein the column decoder is configured to determine that the received address is associated with the second portion of the memory array based on the received address.

4. The apparatus of claim 1, wherein the at least one column in the second portion of the memory array comprises a column configured for per row activation counting (PRAC).

5. The apparatus of claim 4, further comprising:
a first set of conductive lines coupling the column decoder to the memory array;
a second set of conductive lines coupling the column decoder to the column repeater; and
a third set of conductive lines coupling the column repeater to the second portion of the memory array.

6. The apparatus of claim 5, wherein the first set of conductive lines couples the column decoder to the first portion and the second portion of the memory array.

7. The apparatus of claim 1, wherein the column selection signal is provided responsive to a background refresh command.

8. The apparatus of claim 7, further comprising:
a refresh control circuit configured to provide the background refresh command and the address.

9. The apparatus of claim 1, further comprising:
a row decoder configured to provide a row activation signal to at least one row in the second portion of the memory array.

10. A method comprising:
receiving, at a column decoder, a background refresh command including a refresh address;
determining whether the refresh address is associated with a first portion of a memory array or a second portion of the memory array;
providing, by the column decoder, a column selection signal responsive to the background refresh command, wherein the column selection signal is provided to a column repeater when the refresh address is associated with the second portion of the memory array; and
providing, by the column repeater, the column selection signal to at least one column in the second portion of the memory array when the refresh address is associated with the second portion of the memory array.

11. The method of claim 10, wherein the column decoder determines whether the refresh address is associated with the first portion of the memory array or the second portion of the memory array based on the refresh address.

12. The method of claim 10, wherein the at least one column in the second portion of the memory array comprises a column configured for per row activation counting (PRAC), and wherein a PRAC bit is set responsive to the column selection signal.

13. The method of claim 10, wherein the column repeater is disposed between the first portion of the memory array and the second portion of the memory array.

14. The method of claim 10, wherein the background refresh command is received from a refresh control circuit.

15. The method of claim 10, wherein the column selection signal is provided by the column repeater to the at least one column in the second portion of the memory array via a second set of conductive lines that is different from a first set of conductive lines that couple the column decoder to the first portion of the memory array.

16. The method of claim 10, further comprising:
performing an access operation on at least one memory cell in the first portion of the memory array.

17. The method of claim 10, further comprising:
providing, by a row decoder, a row activation signal at a row in the second portion of the memory array.

18. An apparatus comprising:
a memory array comprising a first address space and a second address space;
a row decoder configured to provide a row activation signal to a row in the memory array based on a received address;
a column decoder configured to provide a column selection signal to a column in the memory array; and
a column repeater configured to receive the column selection signal and provide the column selection signal to the column in the memory array when the received address is associated with the second address space.

19. The apparatus of claim 18, wherein the row decoder is configured to provide the row activation signal to a first row in the first address space and provide the row activation signal to a second row in the second address space.

20. The apparatus of claim 18, further comprising a refresh control circuit configured to cause performance of a refresh operation in the second address space independent of an access operation performed in the first address space.

21. The apparatus of claim 18, wherein the column repeater is disposed between the first address space and the second address space.

22. The apparatus of claim 18, wherein the column decoder is coupled to a set of columns associated with the first address space via a first set of conductive lines and the column repeater is coupled to a second set of columns associated with the second address space via a second set of conductive lines.

23. The apparatus of claim 18, wherein the column decoder is configured to determine whether the received address is associated with the first address space or the second address space based on the received address.

24. The apparatus of claim 18, wherein the column in the memory array comprises a column configured for per row activation counting (PRAC).
